(19) United States
(12) Patent Application Publication
(10) Pub. No.: US 2006/0255789 A1
(43) Pub. Date: Nov. 16, 2006

(54) Handheld scanning subsurface detector

(75) Inventors: Christoph Wuersch, Werdenberg (CH); Wilfried Kaneider, Feldkirch-Tosters (AT)

Correspondence Address: ABELMAN, FRAYNE & SCHWAB, 666 THIRD AVENUE, 10TH FLOOR, NEW YORK, NY, 10017, US

(73) Assignee: Hilti Aktiengesellschaft

(21) Appl. No.: 11/397,591

(22) Filed: Apr. 3, 2006

(30) Foreign Application Priority Data
May 10, 2005 (DE) 10 2005 000 054.1

(51) Int. Cl. G01R 19/00

(52) U.S. Cl. 324/67

(57) ABSTRACT

A handheld scanning subsurface detector (1) has a handheld housing (4) which is designed to be guided at a predetermined distance over a wall surface (3) to be examined within a distance (A) from the wall, a sensor device (5) which is sensitive in the electromagnetic high-frequency range, and electromagnetically active shielding elements which shield the intervening distance (A) from the wall from the electromagnetic stray radiation in the high-frequency range, at least within a large circumferential area of a shielding contour (9) that surrounds the sensor device (5) externally.

### BACKGROUND OF THE INVENTION

1. Field of the Invention

The present invention relates to a handheld scanning subsurface detector, particularly for detecting reinforcements or lines embedded in concrete or masonry.

2. Description of the Prior Art

The detection of embedded objects plays an important role in the constructional industry for detecting iron reinforcements, metal pipes, electric lines, or plastic conduits. The detection measurement methods upon which the subsurface detection is based are not the subject matter of the present application and will not be discussed in detail. Generally, embedded objects are detected and identified by changes in the impedance of an impressed magnetic near-field, e.g., according to U.S. Pat. No. 6,541,965, by changes in the impedance of an impressed electric near field according to WO 02063343, or electromagnetically by radar according to U.S. Pat. No. 5,541,605.

Wall surfaces which are coarse and rough (with flatness disparities amounting to several mm) are common, particularly in the constructional industry. By wall surface, it is meant, within the meaning of the invention, surfaces of walls, ceilings, floors, etc. which are at least partially flat.

According to German Publication DE 10207477, a subsurface detector of the type mentioned above with a handheld housing with guide wheels and with a sensor device arranged on the wall side, is moved back and forth over the wall surface to be examined so as to scan it in one dimension. In the associated measurement method, according to EP 1478949, a sensor device is excited with broadband, high-frequency measurement pulses in the high-frequency range between 100 MHz and 10 GHz, and in this way, the complex impedance of the subsurface is measured for different frequencies. It can be concluded indirectly from a change in impedance that objects are embedded in the subsurface. In principle, this type of measurement of changes is very sensitive to external interference near the frequency range to be measured. However, due to the air gap between the guide wheels that is present when scanning in the space between the sensor device and the wall surface, interference particularly from electromagnetic stray radiation reaches the sensor device without being damped and which accordingly leads to false measurements.

Also, a subsurface detector is known previously from Japanese document JP 1282490 in which its sensor device is slid along the wall surface to be examined on a slide. The sensor device is shielded electromagnetically by shielding means in the entire half-space on the housing side up to the slide.

Also, according to JP 11118942, the shielding means in a subsurface detector comprise material which is absorbent or impenetrable with respect to electromagnetic radiation.

Materials absorbing electromagnetic radiation are usually ferroelectric or superparaelectric materials; materials that are impenetrable to electromagnetic radiation are usually electrically conductive materials, for example.

It is the object of the invention to realize a handheld scanning subsurface detector which is highly resistant to interference.

### SUMMARY OF THE INVENTION

This and other objects of the present invention, which will become apparent hereinafter, are achieved by providing a handheld scanning subsurface detector with a handheld housing which is designed for guiding at a predetermined distance over a wall surface to be examined within a distance from the wall and which has a sensor device sensitive in the electromagnetic high-frequency range. Electromagnetically active shielding means is provided which shields the intervening distance from the wall from the electromagnetic stray radiation in the high-frequency range, at least within a large circumferential area of a shielding contour that surrounds the sensor device externally.

The sensor device can be made substantially more resistant to interference by the shielding means for shielding the sensor device from the electromagnetic stray radiation penetrating the intervening distance from the wall.

The shielding means advantageously comprises at least one or more layers of an electrically conductive material, so that a sufficient shielding from electromagnetic radiation in the high-frequency range can be achieved in an economical manner based on the skin effect. Highly permeable materials (ferrite, plastoferrite) and/or highly dielectric materials (barium titanate) are also well suited for shielding because of the hysteresis loss.

The shielding means is advantageously arranged circumferentially at the housing, at least partially, so that the effect of the shielding is improved over the maximum distance from the sensor device. Suitable shielding means of this kind is, for example, absorbent or conductive wheels or tracks which are arranged closely adjacent to one another and longitudinally and/or transversely with respect to the scanning direction.

The shielding means advantageously projects freely from the housing on the wall side into the area of the intervening distance from the wall, so that the shielding means is fixed only on the housing side. Suitable shielding means of this type is, for example, absorbent or conductive spring elements such as lattice structures.

The shielding means is advantageously flexible so that the intervening distance from the wall can be filled so as to be closed to a great extent by the shielding means even when used on coarsely rough wall surfaces, without a significant obstruction of the scanning movement through friction, snagging, jamming, etc. on the wall surface. Suitable flexible shielding means is, for example, absorbent or conductive foamed materials and elastomers, bellows (rounded on the wall side), spring elements such as coil springs arranged close together, or spring-mounted rails.

The shielding means is formed, advantageously, at least partially planar so that the flexibility of the structural components can be achieved substantially by bending them in the plane. To a great extent, planar shielding means is also not dependent upon polarization. Suitable planar shielding means is, for example, absorbent or conductive spring sheet metals, textiles or fibrous materials.

The shielding means is formed advantageously as at least partially elongate elements so that their flexibility can be achieved substantially by bending along the length. Suitable elongate shielding means are, for example, absorbent or conductive bristles or fiber bunches.

Any combination of these different shielding means within the meaning of the invention is also possible.

The novel features of the present invention, which are considered as characteristic for the invention, are set forth in the appended claims. The invention itself, however, both as to its construction and its mode of operation, together with additional advantages and objects thereof, will be best understood from the following detailed description of preferred embodiments, when read with reference to the accompanying drawings.

### BRIEF DESCRIPTION OF THE DRAWINGS

The drawings show:

FIG. 1 a side view of the subsurface detector with guide wheels;

FIG. 2 a plan view of another embodiment of the subsurface detector according to the present invention;

FIG. 3 a plan view of a further embodiment of the subsurface detector according to the present invention; and

FIG. 4 a schematic bottom view of the shielding means.

### DETAILED DESCRIPTION OF THE PREFERRED EMBODIMENTS

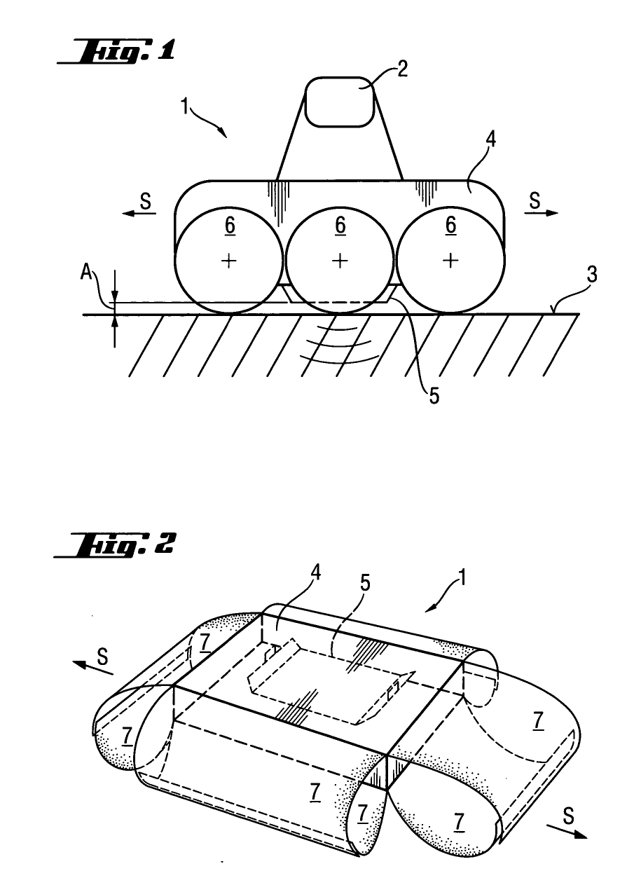

According to FIG. 1, a handheld subsurface detector 1 which scans along a scanning direction S has a housing 4 which can be held by a handle 2 and which is formed for being guided in a predetermined manner at an intervening distance (A) from the wall along a wall surface 3 to be examined. In addition, the subsurface detector 1 has a sensor device 5 which is oriented toward the wall side and which is formed as a planar antenna 1 for the electromagnetic high-frequency range from 100 MHz to 10 GHz. Shielding means is arranged on each longitudinal side of the housing 4 (the side oriented longitudinal to the scanning direction S) for shielding against electromagnetic radiation. The shielding means is formed as three full-surface, radially large guide wheels 6 which are arranged closely adjacent to one another and which are formed of conductive, magnetic plastic material that absorbs electromagnetic radiation and comprises carbon particles and ferrite grains. These shielding means accordingly extend over the intervening distance A from the wall with respect to most of the planar portion and circumferentially around the sensor device 5 with respect to most of the circumferential area.

In an alternative subsurface detector 1 which is shown only schematically in FIG. 2 and which has a sensor device 5 that is oriented toward the wall side, the shielding means has flexible lamellas 7 which are bent along the surface and are made from polymer foils with electrically conductive coating. The lamellas 7, which project freely on one side, are arranged circumferentially at each of the four sides of the housing 4 and accordingly substantially surround the sensor device 5 circumferentially. Two lamellas 7 which are arranged on the same side but which project out differently (on the wall side and laterally), partially engage one inside the other at the ends.

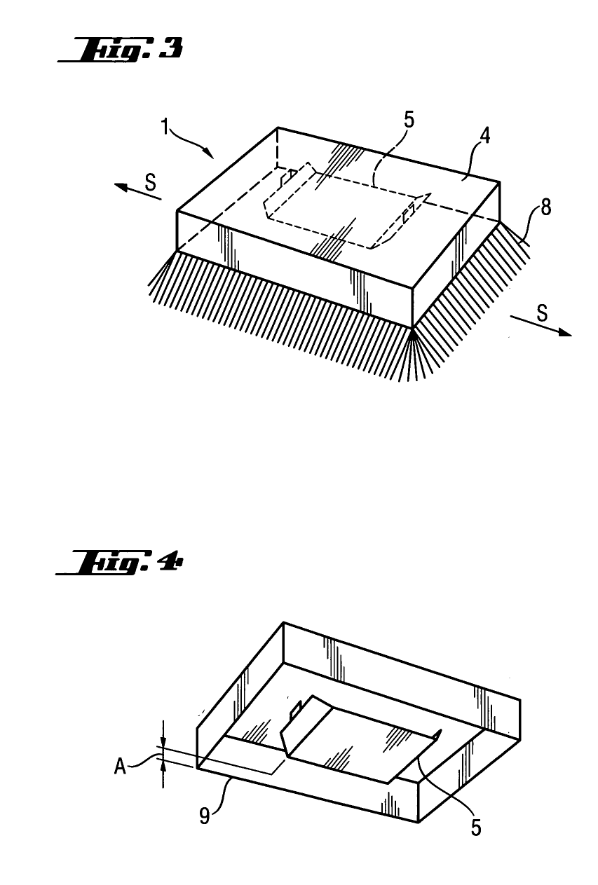

In an alternative subsurface detector 1 which is shown only schematically in FIG. 3 and which has a sensor device 5 that is oriented toward the wall side, the shielding means has a plurality of thin, elongated bristles 8 of metal which project freely from the circumference of the housing 4 on the wall side and which accordingly completely surround the sensor device 5 circumferentially.

According to FIG. 4 which schematically shows the shielding means viewed from the bottom (that is, from the wall side), the sensor device 5, which is formed as a planar antenna and which is sensitive to the electromagnetic high-frequency range, is ideally shielded by a generally geometric shielding contour 9 which shields against electromagnetic stray radiation in the high-frequency range over the entire intervening distance A from the wall and over the entire circumferential area. The shielding means, which surrounds the sensor device 5 externally, is formed, for example, specifically by guide wheels 6 according to FIG. 1, by lamellas 7 according to FIG. 2, or by bristles 8 according to FIG. 3.

Though the present invention was shown and described with references to the preferred embodiments, such are merely illustrative of the present invention and are not to be construed as a limitation thereof and various modifications of the present invention will be apparent to those skilled in the art. It is, therefore, not intended that the present invention be limited to the disclosed embodiments or details thereof, and the present invention includes all variations and/or alternative embodiments within the spirit and scope of the present invention as defined by the appended claims.

What is claimed is:

1. A handheld scanning subsurface detector, comprising a handheld housing (4) to be guided at a predetermined distance over a wall surface (3); a sensor device (5) which is sensitive in the electromagnetic high-frequency range and is secured to the housing (4); and electromagnetically active shielding means for shielding the intervening distance (A) from the wall from an electromagnetic stray radiation in a high-frequency range at least within a large circumferential area of a shielding contour (9) that surrounds the sensor device (5) externally.

2. A subsurface detector according to claim 1, wherein the shielding means comprises at least one layer of an electrically conductive, permeable and/or dielectric material.

3. A subsurface detector according to claim 1, wherein the shielding means is arranged circumferentially at the housing (4) at least partially.

4. A subsurface detector according to of claim 1, wherein that the shielding means freely projects from the housing (4) on the wall side thereof into an area of the intervening distance (A).

5. A subsurface detector according to claim 1, wherein the shielding means is flexible.

6. A subsurface detector according to claim 1, wherein the shielding means is at least partially planar.

7. A subsurface detector according to claim 1, wherein the shielding means is at least partially elongated.
